(19) United States
(12) Patent Application Publication
(10) Pub. No.: US 2025/0293647 A1
(43) Pub. Date: Sep. 18, 2025

(54) SWITCHED CAPACITOR CHARGE PUMP CIRCUIT WITH FINE IMPEDANCE CONTROL

(71) Applicant: QUALCOMM Incorporated, San Diego, CA (US)

(72) Inventors: Ganesh KIRAN, San Diego, CA (US); Vijayakumar DHANASEKARAN, San Diego, CA (US); Qubo ZHOU, San Diego, CA (US)

(21) Appl. No.: 18/604,893

(22) Filed: Mar. 14, 2024

(51) Int. Cl. H03F 3/213; H02M 3/07; H03F 1/08; H03F 3/185

(52) U.S. Cl. CPC H03F 3/213; H02M 3/07; H03F 1/086; H03F 3/185

(57) ABSTRACT

Aspects relate to a switched capacitor charge pump circuit with fine impedance control. An apparatus includes an input node that receives a supply voltage, an output node that alternately provides a first voltage and a second voltage, a plurality of parallel switch paths between the input node and the output node, and a flying capacitor coupled in parallel to the parallel switch paths to provide the first or the second voltages based on a control signal. A number of the parallel switch paths are configured to be activated and operated at a switching frequency in response to the control signal.

### TECHNICAL FIELD

Aspects of the present disclosure relate generally to switched capacitor charge pump circuits and, in particular, to charge pump circuit with fine impedance control.

### BACKGROUND

A switched capacitor charge pump is used to provide Direct Current (DC) power to an amplifier, e.g., a Class G or Class H amplifier. Charge pumps are small and inexpensive to fabricate in semiconductor circuitry. Switched capacitor charge pumps may be configured for a voltage step-up, a voltage step-down and for multi-level voltage outputs. Switched capacitor charge pumps notably avoid the cost of an external or even an integrated inductor that may be required for a buck converter or a flyback converter.

For many integrated circuit applications, the charge pump is configured to produce one of two different output power levels. When an amplifier frequently operates at partial capacity, e.g., half of its full gain or less, then the power consumption of the charge pump and the amplifier can be reduced by supplying less power from the charge pump to the amplifier. When the amplifier provides higher power, e.g., more than half of its full gain, then the charge pump switches to provide the full power. The charge pump may be controlled by a control signal, that indicates the amplification that the connected amplifier will be providing.

### BRIEF SUMMARY

The following presents a summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

In one example, a charge pump circuit, includes an input node that receives a supply voltage, an output node that alternately provides a first voltage and a second voltage, a plurality of parallel switch paths between the input node and the output node, and a flying capacitor coupled in parallel to the parallel switch paths to provide the first or the second voltages based on a control signal, wherein a number of the parallel switch paths are configured to be activated and operated at a switching frequency in response to the control signal.

In one example, a method includes receiving a supply voltage at an input node of a charge pump, receiving a control signal at the charge pump, activating a number of a plurality of parallel switch paths of the charge pump as active switch paths in response to the control signal, and operating the active switch paths at a switching frequency in response to the control signal to generate a first voltage or a second voltage at an output node of the charge pump.

In one example, an audio system includes audio logic configured to generate a control signal and an analog audio signal in response to a digital audio signal. A charge pump circuit is coupled to the audio logic and to a supply voltage. The charge pump circuit has a plurality of parallel switch paths coupled in parallel to a flying capacitor and configured to receive the supply voltage and alternately provide a first voltage or a second voltage, the charge pump having a controller to receive the control signal and configured to set a number and switching frequency of the parallel switch paths to be active. At least one power amplifier is coupled to the audio logic and to the charge pump circuit and configured to amplify the analog audio signal using the first voltage and the second voltage in response to the control signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the described implementations are intended to include all such aspects and their equivalents.

### BRIEF DESCRIPTION OF THE DRAWINGS

FIG. 1 is a diagram of an audio system using a two-level charge pump, in accordance with aspects of the disclosure.

FIG. 2 is a diagram of an audio system using a two-level charge pump for two independent power amplifiers, in accordance with aspects of the disclosure.

FIG. 3 is a diagram of a two-level charge pump having multiple parallel switching paths and fine impedance control in accordance with aspects of the disclosure.

FIG. 4 is table of power amplifier voltages and charge pump operation parameters in accordance with aspects of the disclosure.

FIG. 5 is a process flow diagram of a process of operating a charge pump with fine impedance control in accordance with aspects of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, these concepts may be practiced without these specific details. In some instances, well-known structures and components are shown in block diagram form in order to avoid obscuring such concepts.

The described charge pump has an input node that receives a supply voltage and an output node that alternately provides a first voltage and a second voltage. A plurality of parallel switch paths is coupled between the input node and the output node through a flying capacitor. The parallel switch paths are coupled in parallel to the flying capacitor to provide the first and the second voltages based on a control signal. A number of the parallel switch paths are active and operated at a switching frequency in response to the control signal.

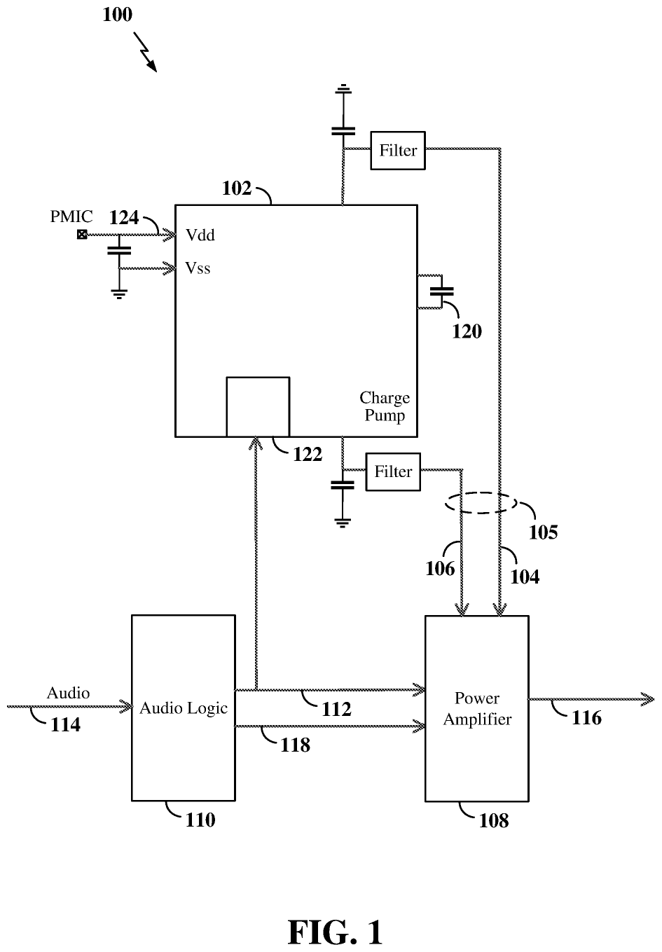

FIG. 1 shows an audio system 100 with a charge pump 102 configured to provide multiple levels of power to a power amplifier 108 using the number and operating frequency of multiple parallel switch paths. The charge pump 102 supplies two levels of power output through a positive power output port 104 and a negative power output port 106, based on a received control signal 112 from audio logic 110 based on a digital audio signal 114. The charge pump 102 operates at high efficiency to supply a power amplifier (PA) 108, e.g., a Class G or Class H power amplifier, inter alia. The impedance of the output signal may be finely modulated based on the level of the received control signal 112 to improve efficiency above other charge pumps. A flying capacitor 120 may be coupled to the charge pump 102 to provide positive and negative supplies at the positive power output port 104 and the negative power output port 106 at two or more levels. The flying capacitor 120 may be external to the charge pump and to the other circuitry for higher precision, ease of fabrication, and other purposes. For a power management integrated circuit (PMIC) that delivers a supply voltage of 1.8V between Vdd and Vss at an input node 124 of the charge pump, a first level of power output at the output node 105 may be a gain of 1 and the second level of output power may be a gain of 0.5, e.g., +/−1.8V and +/−0.9V, or a full voltage and half voltage. The parallel switch paths are coupled in parallel to the flying capacitor 120. In other examples, there may be more than one flying capacitor each coupled to a subset of the plurality of parallel switch paths.

Other voltages and additional voltages may be provided to suit different implementations. The principles described herein may be applied to step up, step down and multi-level charge pumps, inter alia. The charge pump is suited for use with High Power Headphones (HPH) and Earpiece Power Amplifiers (PAs). At the same time, the equivalent resistance of the charge pump may be low enough to support a 1 Vrms signal onto a 32 Ohm load with low distortion.

In examples herein, the audio logic 110 receives a digital audio signal 114 as an input that is to be amplified by the power amplifier 108. The audio logic 110 generates the control signal 112, e.g., in the form of an 8-bit control word. The multiple bits of the control word may contain more or fewer than 8 bits and may be truncated. The control signal 112 is supplied to the charge pump 102 and to the power amplifier 108 that is coupled to the charge pump 102. The charge pump 102 uses the control signal 112 to configure the output power to the power amplifier 108. The output power of the charge pump 102 at the output node 105, having the positive power output port 104 and the negative power output port 106, is configured to provide all the power that the power amplifier 108 requires to amplify an amplifier input signal, which is an analog audio signal 118 processed by the audio logic 110 with sufficient reserve power or amplifier headroom for quick signal variations.

The audio logic 110 may be a part of a digital signal processor, a digital-to-analog converter (DAC) or another component that has access to or processes the digital audio signal 114. The control signal 112 may be in an analog or digital form. For a Class G or Class H power amplifier, a Class H codes, which is an 8-bit control word that represent a playback data level, may be used. The Class H code of the control signal 112 is used to set the charge pump 102, the power supply to the power amplifier 108 based on the power amplifier output signal and headroom requirement. The control signal 112 is also provided to the power amplifier 108 for use in amplifying the analog audio signal 118 which is generated by the audio logic 110 based on the digital audio signal 114. A Class H codes may be regarded as lower resolution and time advanced versions of the digital audio signal 114 or playback data that will be sent to the power amplifier 108. The lower resolution comes from some processing at the audio logic 110. The time advance ensures enough time for settling of the charge pump power output and enough time to maintain the desired headroom at the charge pump output node 105. As such, Class H codes in the form of control words are easily generated using a digital block coupled to the digital audio signal 114. This data to be played back by the power amplifier 108 is known at the audio logic 110 a priori and, in many implementations, is available in a digital format.

The charge pump 102 generates power to the output node 105 that may have two different possible values. When the power amplifier 108 output 116 is close to its maximum, the charge pump 102 is set by the control signal 112 to have a high gain, e.g., a gain of 1. In other words, the power outputs are approximately +Vdd on the positive power output port 104 and −Vdd on the negative power output port 106. When the power amplifier 108 output 116 is low, then the charge pump gain is set to a lower value. This may be one half of the full power or another value. In other words, the power outputs are approximately +0.5 Vdd on the positive power output port 104 and −0.5 Vdd on the negative power output port 106.

The transition from the gain of 1 to the gain of 12 depends on the control signal 112 and may be chosen such that when the charge pump 102 switches its output to a gain of ½, the power amplifier 108 still has enough headroom. The amount of headroom considered to be enough will vary depending on the nature of the power amplifier 108 and the use to which the power amplifier is applied. In some integrated circuit examples, sufficient headroom may be considered to be about 200 mV, for a Vdd of about 1.8V.

Reducing the gain to ½ significantly improves the efficiency of the audio system 100 compared to using a full gain, e.g., a constant +/−1.8 supply, at all times. However, at very low signal levels, the internal current consumption of the charge pump 102 becomes significant in comparison to other power consumption in the audio system 100. This degrades the efficiency of the audio system 100 so far that the power consumption at low signal levels may be worse than simpler Class H amplifier systems.

Higher switching frequencies may be limited to a maximum switching frequency in order to reduce the resistance of the charge pump at high output power levels and increase the headroom for the power amplifier. Additionally, the switches in the charge pump are sized to have a certain resistance for the high gain circumstances when the power amplifier output is at its maximum. However, at lower power amplifier outputs, a higher charge pump output resistance may be used to reduce power consumption. The power amplifier is able to operate at higher resistance because it has more headroom when the amplitude swing of the output is lower.

The charge pump 102 operates by switching the power from the input node 124 through the flying capacitor 120 at different frequencies. While the flying capacitor 120 is shown as being external to the charge pump 102, hence it is flying, the flying capacitor 120 may be integrated with the charge pump 102 and fabricated on the same substrate. The power consumed by the internal circuitry of the charge pump 102 is proportional to the switching frequency (Fsw) and the size of the switches being switched. The resistance of the charge pump 102 is a combination of the effect of the flying capacitor 120 being switched, the series resistance of the flying capacitor 120, the switch on resistance, and the various parasitic resistances through the circuits, routing and packaging. The effect of the flying capacitor 120 being switched affects the resistance as the inverse of the switching frequency. At lower switching frequencies, the resistance is dominated by the effect of the flying capacitor 120 being switched. At higher switching frequencies the series resistance of the flying capacitor 120 and the switch on resistance are the primary contributors of the resistance.

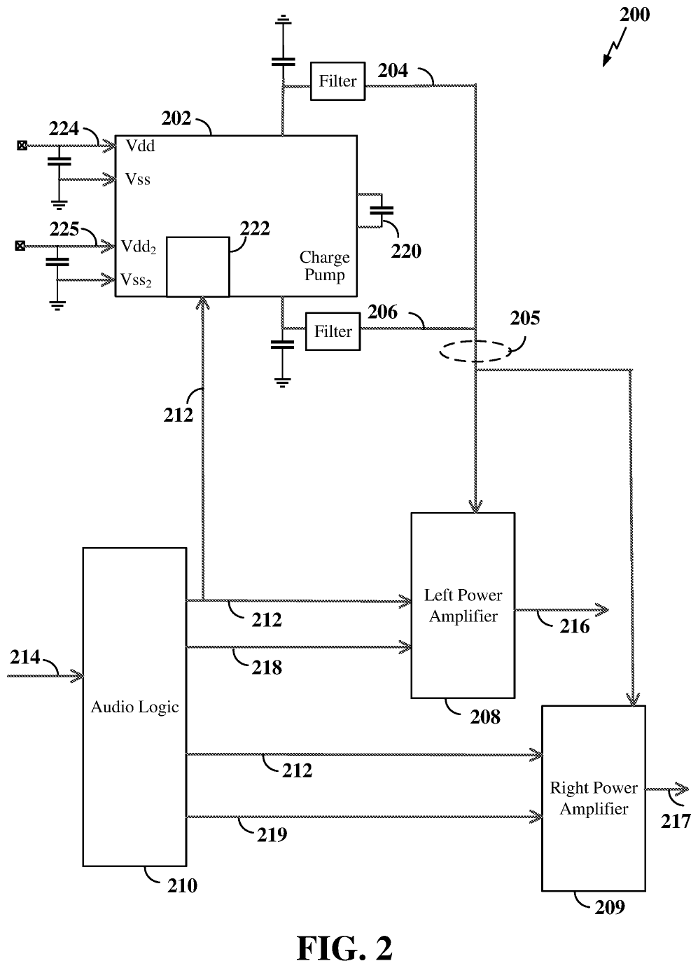

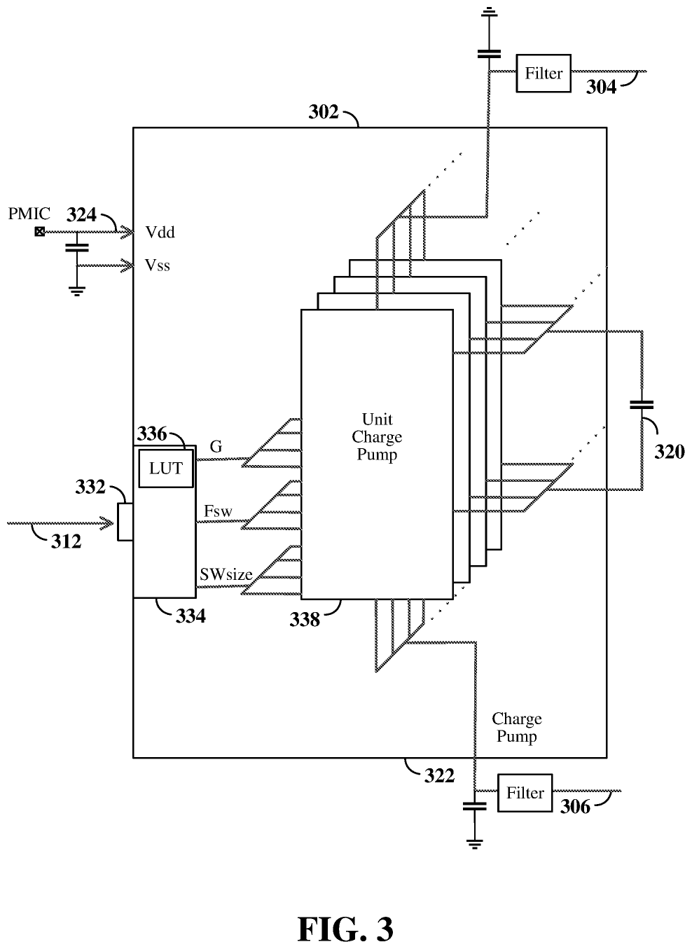

FIG. 2 is a diagram of an audio system using a two-level charge pump for two independent power amplifiers 108, 109. The charge pump 202 may be configured to provide multiple levels and different levels of power to the power amplifiers 208, 209 using the number and operating frequency of multiple parallel switch paths. The charge pump 202 supplies two levels of voltage as the power output from one input node 224 through a positive power output port 204 and a negative power output port 206, based on a received control signal 212 from audio logic 210 based on an input audio signal 214. The charge pump may be configured to provide five different levels or voltages of power output from two input nodes, the input node 224 as in FIGS. 1 and 3 for a first supply voltage and a second input node 225, with a second supply voltage that is a different supply voltage, either lower or a higher, through the positive power output port 204 and the negative power output port 206. Additional switching is provided within the charge pump 202 to accommodate the two input nodes 224, 225 and provide the additional power output levels. The examples of FIGS. 1 and 3 may also be adapted to support two or more input nodes and a third power output level, a fourth power output level and a fifth power output level by using the two input nodes together. An external flying capacitor 220 may be coupled to the charge pump 202 to provide positive and negative supplies at the positive power output port 204 and the negative power output port 206 at two or more levels.

In examples herein, the audio logic 210 receives a digital audio signal 214 that is to be amplified by the power amplifiers 208, 209. The digital audio signal 214 may be a stereo signal with a left channel and a right channel. The audio logic 210 generates the control signal 212, e.g., in the form of an 8-bit Class G code or Class H code. The control signal 212 is supplied to the charge pump 202, to the left power amplifier 208 and to the right power amplifier 209 that are also coupled to the charge pump 202. The control signal 212 may be the same for the left power amplifier 208 and the right power amplifier 209 or the audio logic 210 may generate a left control signal for the left power amplifier 208 and a right control signal for the right power amplifier 209. The charge pump 202 uses the control signal 212 which may be a left, right, or combined control signal to configure the output power to the power amplifiers 208, 209. In examples, the output power is the same to both of the power amplifiers 208, 209, as shown.

The audio logic 210 generates a left analog audio signal 218 that is coupled to the left power amplifier 209. The left power amplifier 208 amplifies the left analog audio signal 218 using the supplied power from the output node 205 of the charge pump 202 to generate a left output 216. Similarly, the audio logic 210 generates a right analog audio signal 219 that is coupled to the right power amplifier 209. The right power amplifier 209 amplifies the right analog audio signal 219 using the supplied power from the output node 205 of the charge pump 202 to generate a right output 217. The output power of the charge pump 202 is configured to provide all the power that the power amplifiers 208, 209 require to amplify the left analog audio signal 218 and the right analog audio signal 219 as the left analog audio signal 218 and the right analog audio signal 219 vary and the amplification needs vary. The impedance of the power output at the output node 205 may be finely modulated as described in more detail in the context of FIG. 3.

The audio logic 210 and the charge pump 202 may be configured and constructed as described with respect to FIG. 1. The charge pump 202 operates by switching the power from the input node 224 through the flying capacitor 220 at different frequencies as in the example of FIG. 1. While a left power amplifier 208 and a right power amplifier 209 are shown, the amplifiers may have other designations or purposes. Any two or more power amplifiers may be coupled to the output node. Accordingly, a first analog audio signal may be amplified by a first power amplifier and a second analog audio signal may be amplified by a second power amplifier. The charge pump 202 is configured to generate sufficient power for both the first power amplifier and the second power amplifier simultaneously.

FIG. 3 is a diagram of a two-level charge pump 302 suitable for driving a Class H or Class G power amplifier in some implementations. The two-level charge pump 302 has an input node 324 to receive the input voltage, e.g. Vdd, and an output node 304, 306 with a positive power output port and a negative power output port, respectively. The charge pump 302 has a control signal input port 332 to a controller 334, e.g., a code interpreter, including a lookup table 336. The controller 334 receives a control signal 312, e.g., a Class H code, at the control signal input port 332, applies the control word to the lookup table 336, and generates control outputs in response to the result from the lookup table 336. The control outputs may come in the form of a gain state (G) output, a switching frequency (Fsw) output, and a switch size (SWsize) output. The selection of the parameters from the controller 334 allows the controller 334 to select a suitable impedance for the charge pump 302 for the operation conditions indicated by the control signal 312.

The charge pump 302 includes multiple unit charge pumps 338, e.g., 8 or 12, etc., which are connected in parallel. Each unit charge pump 338 provides a switch path between the input node 324, or power input, and the output node 304, 306 to generate the voltage at the output node 304, 306. A flying capacitor 320 is coupled to each of the parallel switch paths to provide the first and second voltages of the two-level charge pump 302. The gain state (G) and the switching frequency (Fsw) refer to the operation of the unit charge pumps 338 by the controller 334. The switch size (SWsize) refers to the number of parallel switch paths that are active, e.g. 3, 6, 9, or 12, etc., parallel switch paths. More switch paths create more resistance as they are switched.

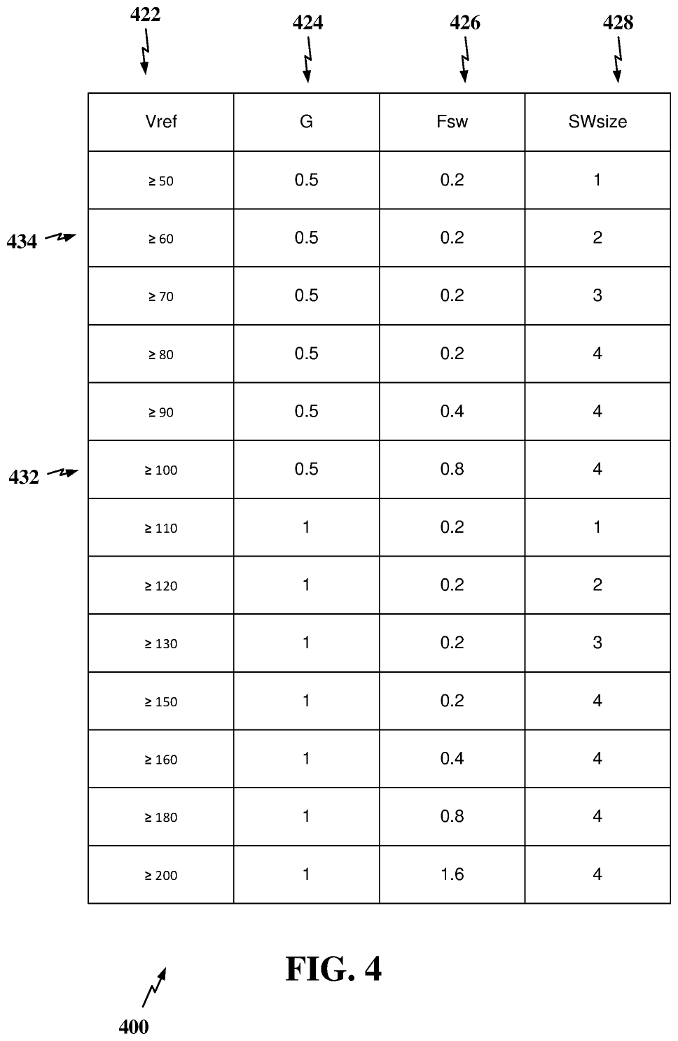

FIG. 4 is an example table of power amplifier voltages and charge pump operation parameters suitable for use with a two-level charge pump as described herein. The lookup table 400 is a table of numbers that may be adapted to suit more power levels, different numbers of switching frequencies and different numbers of parallel switch paths. While an 8-bit control word has 256 different states, the lookup table 400 has only 13 different states or rows. The least significant 4 bits of the control word may be ignored to better map the control word to the rows of the table. In an example, the voltage level at each row may be unequal or nonlinear relative to other rows so that additional bits of the control word are used to accurately map the control word to a row.

The control signal may be in the form of a control word, e.g., an 8-bit Class H code, that represents a voltage that is mapped to a first column, the voltage column 422. As mentioned above, the example lookup table has a row for each of 13 different voltage ranges. Each row then maps to a gain column 424 with one of two gain levels, 0.5 and 1.0. This may be represented with 1 bit and corresponds to the two levels of the two-level charge pump. For other charge pumps there may be more than two gain levels for the 13 or more different voltage ranges. Each row also maps to a switching frequency, Fsw column 426, represented as having one of four different levels in MHz, 0.3, 0.6, 1.2, 2.4, although any other frequencies may be used. This may be represented with 2 bits. Finally, each row maps to a switch size, SWsize column 428 represented as having four levels, 1, 2, 3, and 4. The four levels may be represented with 2 bits, and each correspond to a number of parallel switch paths. In examples, the numbers correspond to 25%, 50%, 75%, and 100% of the switch paths being active, although other percentages may be used, and a linear relationship is not required. For a charge pump with 12 parallel switch paths, 1 may represent 3 switch paths, 2 may represent 6 switch paths, 3 may represent 9 switch paths, and 4 may represent all 12 switch paths. For other configurations, the values may represent other numbers of paths.

The lookup table 400 represents possible combinations of parameters that may be used in particular implementations and with particular charge pump configurations. Other parameters may be used in other circumstances and for other charge pumps. The results from the lookup table may be obtained by reading from a lookup table stored in a non-transitory storage device, e.g., a content-addressable memory or in another way, e.g., combinatorial logic circuits or software.

Referring to FIG. 3, the controller 334 may separately access the switch gate controls of each unit charge pump 338 separately through the G, Fsw, and SWsize outputs. This allows the controller 334 to provide power saving operational modes in response to the control signal 312. The controller 334 uses the information in the control signal 312 to switch between different gain modes, switching frequencies, and switch sizes as suggested by the lookup table 400. The control signal 312 represents a power amplifier power output, similar to a reference voltage value (Vref), which in some examples, may be received as an 8-bit control word, e.g., (Vref) from a digital Class H audio logic block. In this way, Vref is used to set a 2-bit Fsw and to set a 2-bit SWsize control.

Referring to FIG. 4, the 13 different voltages in the voltage column 422 for Vref may be considered as a lookup table in which Vref is compared against thresholds to determine key control parameters for the charge pump. The 13 different voltages may be made programmable to allow for changes to be programmed to accommodate different power amplifiers and different charge pump configurations.

In use, when the power amplifier output gets lower, then the Vref will be mapped to a higher row of the lookup table. This will reduce Fsw and SWsize, resulting in higher output resistance for the charge pump. However, the power amplifier headroom will be increased due to the lower gain and output power of the power amplifier. As an example, at the sixth row 432 with Vref greater than 100 mV and less than 110 mV, Fsw is 0.8 and SWsize is 4. A reduced Vref, at the second row 434, greater than 60 mV and less than 70 mV gives an Fsw of 0.2 and SWsize of 2. This corresponds to a reduced switching frequency and number of switch paths for a higher resistance. While the resistance is higher, switch driver current, a significant contributor to charge pump internal power consumption, is reduced at the lower frequency and number of switches. Each of the entries in the table may be selected to control the impedance for each control signal input.

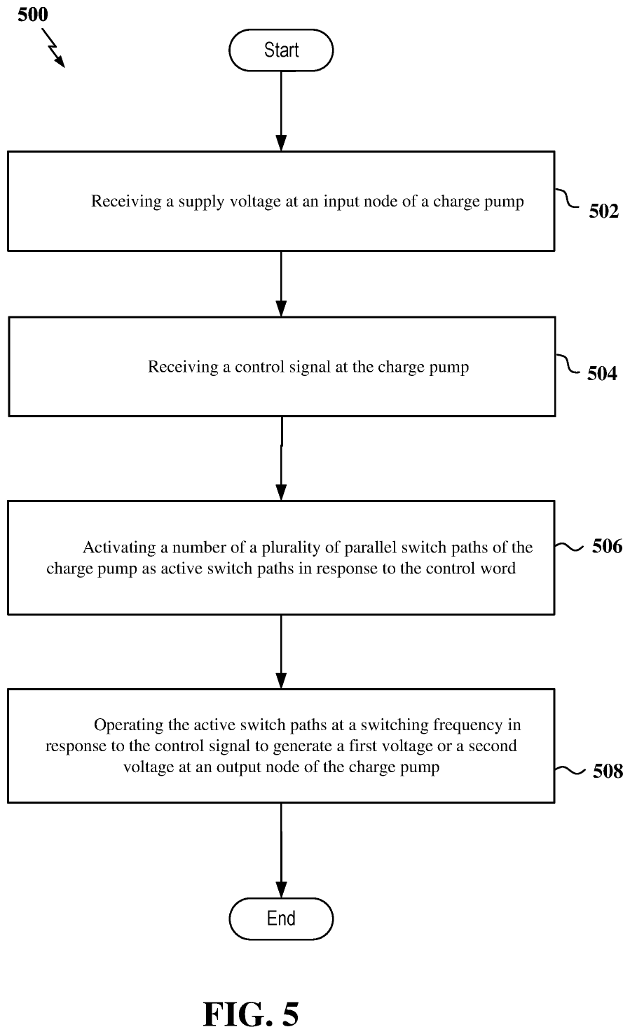

FIG. 5 is a process flow diagram of a process of operating a multiple-level charge pump with fine impedance control according to some aspects. At block 502, the process includes receiving a supply voltage at an input node of a charge pump. The supply voltage may be between Vdd and Vss or any other suitable supply voltage may be used.

At block 504, receiving a control signal at the charge pump is performed. The control signal may be an analog or digital value. While the description is presented in the context of a Class H control word, any other representation of the power amplifier output power may be used.

At block 506, the process includes activating a number of a plurality of parallel switch paths of the charge pump as active switch paths in response to the control word.

At block 508, operating the active switch paths at a switching frequency in response to the control signal to generate a first voltage or a second voltage at an output node of the charge pump is performed. The number of active switch paths, and the switching frequency may be selected for fine impedance control over the charge pump. Fine control of the charge pump impedance may be used to reduce the power consumption of the charge pump, particularly at low power levels.

As used herein, “or” is intended to be interpreted in the inclusive sense, unless otherwise explicitly indicated. For example, “a or b” may include a only, b only, or a combination of a and b. As used herein, a phrase referring to “at least one of” or “one or more of” a list of items refers to any combination of those items, including single members. For example, “at least one of: a, b, or c” is intended to cover the examples of: a only, b only, c only, a combination of a and b, a combination of a and c, a combination of b and c, and a combination of a and b and c.

The various illustrative components, logic, logical blocks, modules, circuits, operations, and algorithm processes described in connection with the implementations disclosed herein may be implemented as electronic hardware, firmware, software, or combinations of hardware, firmware, or software, including the structures disclosed in this specification and the structural equivalents thereof. The interchangeability of hardware, firmware and software has been described generally, in terms of functionality, and illustrated in the various illustrative components, blocks, modules, circuits and processes described above. Whether such functionality is implemented in hardware, firmware or software depends upon the particular application and design constraints imposed on the overall system.

The various illustrative logical blocks, modules, and circuits described in connection with the exemplary aspects disclosed herein may be implemented or performed with a general purpose processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A general-purpose processor may be a microprocessor and the processor may be any conventional processor, controller, microcontroller, or state machine. A processor may also be implemented as a combination of computing devices, for example, a combination of a DSP and a microprocessor, a plurality of microprocessors, one or more microprocessors in conjunction with a DSP core, or any other such configuration.

Various modifications to the implementations described in this disclosure may be readily apparent to persons having ordinary skill in the art, and the generic principles defined herein may be applied to other implementations without departing from the spirit or scope of this disclosure. Thus, the claims are not intended to be limited to the implementations shown herein but are to be accorded the widest scope consistent with this disclosure, the principles and the novel features disclosed herein.

Additionally, various features that are described in this specification in the context of separate implementations also can be implemented in combination in a single implementation. Conversely, various features that are described in the context of a single implementation also can be implemented in multiple implementations separately or in any suitable subcombination. As such, although features may be described above as acting in particular combinations, and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one or more example processes in the form of a flowchart or flow diagram. However, other operations that are not depicted can be incorporated in the example processes that are schematically illustrated. For example, one or more additional operations can be performed before, after, simultaneously, or between any of the illustrated operations. In some circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products.

The following provides an overview of examples of the present disclosure.

Example 1: A charge pump circuit, comprising: an input node configured to receive a supply voltage; an output node configured to alternately provide a first voltage and a second voltage; a plurality of parallel switch paths between the input node and the output node; and a flying capacitor coupled in parallel to the parallel switch paths to provide the first or the second voltages based on a control signal, wherein a number of the parallel switch paths are configured to be activated and operated at a switching frequency in response to the control signal.

Example 2: The charge pump circuit of example 1, wherein the parallel switch paths each include a unit charge pump.

Example 3: The charge pump circuit of example 1 or 2, wherein the control signal comprises a control word having multiple bits.

Example 4: The charge pump circuit of example 3, wherein receiving the control word comprises receiving a representation of a voltage of an amplifier input signal, the amplifier being powered by the voltage of the output node.

Example 5: The charge pump circuit of example 3 or 4, wherein the control word comprises a Class H code.

Example 6: The charge pump circuit of example 5, wherein the Class H code represents a playback data level.

Example 7: The charge pump circuit of any one or more of examples 3-6, wherein the control word contains multiple bits and the value of the bits determines the number of the parallel switch paths to be activated and the switching frequency.

Example 8: The charge pump circuit of any one or more of the above examples, further comprising a controller having a control signal input port to receive the control signal at the control input, the controller configured to set the number of the parallel switch paths that are active and to set the switching frequency of the active parallel switch paths in response to the control signal.

Example 9: The charge pump circuit of any one or more of the above examples, wherein the switching frequency is selected to provide an impedance at the output node.

Example 10: The charge pump circuit of example 9, wherein the number of active switch paths is selected to provide an impedance at the output node.

Example 11: The charge pump of any one or more of the above examples wherein the output node is configured to be coupled to a power amplifier to provide the first or the second voltage to the power amplifier.

Example 12: The charge pump of any one or more of the above examples, wherein the output node is configured to be coupled to a first power amplifier and a second power amplifier to simultaneously provide the first or the second voltage to the first power amplifier and the second power amplifier.

Example 13: The charge pump of any one or more of the above examples, further comprising a second input node having a different supply voltage and wherein the output node is configured to alternately provide a third and a fourth voltage from the second input node.

Example 14: A method, comprising: receiving a supply voltage at an input node of a charge pump; receiving a control signal at the charge pump; activating a number of a plurality of parallel switch paths of the charge pump as active switch paths in response to the control signal; and operating the active switch paths at a switching frequency in response to the control signal to generate a first voltage or a second voltage at an output node of the charge pump.

Example 15: The method of example 14, wherein receiving the control signal comprises receiving a representation of a voltage of an amplifier input signal, the amplifier being powered by the voltage at the output node.

Example 16: The method of claim 14 or 15, wherein activating a number of the plurality of parallel switch paths comprises selecting the number using the control signal.

Example 17: The method of example 16, wherein selecting the number comprises applying the control signal to a table of numbers.

Example 18: An audio system comprising: audio logic configured to generate a control signal and an analog audio signal in response to a digital audio signal; a charge pump circuit coupled to the audio logic and to a supply voltage, the charge pump circuit having a plurality of parallel switch paths coupled in parallel to a flying capacitor and configured to receive the supply voltage and alternately provide a first voltage or a second voltage, the charge pump having a controller to receive the control signal and configured to set a number and switching frequency of the parallel switch paths to be active; and at least one power amplifier coupled to the audio logic and to the charge pump circuit and configured to amplify the analog audio signal using the first voltage and the second voltage in response to the control signal.

Example 19: The audio system of example 18, wherein the parallel switch paths each include a unit charge pump.

Example 20: The audio system of example 18 or 19, wherein the control signal comprises a Class H code.

What is claimed is:

1. A charge pump circuit, comprising:
an input node configured to receive a supply voltage;
an output node configured to alternately provide a first voltage and a second voltage;
a plurality of parallel switch paths between the input node and the output node; and
a flying capacitor coupled in parallel to the parallel switch paths to provide the first or the second voltages based on a control signal,
wherein a number of the parallel switch paths are configured to be activated and operated at a switching frequency in response to the control signal.

2. The charge pump circuit of claim 1, wherein the parallel switch paths each include a unit charge pump.

3. The charge pump circuit of claim 1, wherein the control signal comprises a control word having multiple bits.

4. The charge pump circuit of claim 3, wherein receiving the control word comprises receiving a representation of a voltage of an amplifier input signal, the amplifier being powered by the voltage of the output node.

5. The charge pump circuit of claim 3, wherein the control word comprises a Class H code.

6. The charge pump circuit of claim 5, wherein the Class H code represents a playback data level.

7. The charge pump circuit of claim 3, wherein the control word contains multiple bits and the value of the bits determines the number of the parallel switch paths to be activated and the switching frequency.

8. The charge pump circuit of claim 1, further comprising a controller having a control signal input port to receive the control signal at the control input, the controller configured to set the number of the parallel switch paths that are active and to set the switching frequency of the active parallel switch paths in response to the control signal.

9. The charge pump circuit of claim 1, wherein the switching frequency is selected to provide an impedance at the output node.

10. The charge pump circuit of claim 9, wherein the number of active switch paths is selected to provide an impedance at the output node.

11. The charge pump of claim 1, wherein the output node is configured to be coupled to a power amplifier to provide the first or the second voltage to the power amplifier.

12. The charge pump of claim 1, wherein the output node is configured to be coupled to a first power amplifier and a second power amplifier to simultaneously provide the first or the second voltage to the first power amplifier and the second power amplifier.

13. The charge pump of claim 1, further comprising a second input node having a different supply voltage and wherein the output node is configured to alternately provide a third and a fourth voltage from the second input node.

14. A method, comprising:
receiving a supply voltage at an input node of a charge pump;
receiving a control signal at the charge pump;
activating a number of a plurality of parallel switch paths of the charge pump as active switch paths in response to the control signal; and
operating the active switch paths at a switching frequency in response to the control signal to generate a first voltage or a second voltage at an output node of the charge pump.

15. The method of claim 14, wherein receiving the control signal comprises receiving a representation of a voltage of an amplifier input signal, the amplifier being powered by the voltage at the output node.

16. The method of claim 14, wherein activating a number of the plurality of parallel switch paths comprises selecting the number using the control signal.

17. The method of claim 16, wherein selecting the number comprises applying the control signal to a table of numbers.

18. An audio system comprising:
audio logic configured to generate a control signal and an analog audio signal in response to a digital audio signal;
a charge pump circuit coupled to the audio logic and to a supply voltage, the charge pump circuit having a plurality of parallel switch paths coupled in parallel to a flying capacitor and configured to receive the supply voltage and alternately provide a first voltage or a second voltage, the charge pump having a controller to receive the control signal and configured to set a number and switching frequency of the parallel switch paths to be active; and
at least one power amplifier coupled to the audio logic and to the charge pump circuit and configured to amplify the analog audio signal using the first voltage and the second voltage in response to the control signal.

19. The audio system of claim 18, wherein the parallel switch paths each include a unit charge pump.

20. The audio system of claim 18, wherein the control signal comprises a Class H code.
